(19) United States
(12) Patent Application Publication
(10) Pub. No.: US 2007/0001289 A1
(43) Pub. Date: Jan. 4, 2007

(54) Semiconductor device and method of manufacturing the same

(75) Inventor: Noriyuki Takao, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/416,198

(22) Filed: May 3, 2006

(30) Foreign Application Priority Data
Jun. 30, 2005 (JP) 2005-192327

(51) Int. Cl. H01L 23/15; H01L 23/06

(52) U.S. Cl. 257/705

(57) ABSTRACT

A semiconductor device 1 includes a SOI substrate 10, an interconnect layer 20, and an isolation region 30. The SOI substrate 10 includes a supporting substrate 12, an insulating film 14 (substrate insulating film) provided on the supporting substrate 12, and a silicon active layer 16 (silicon layer) provided on the insulating film 14. Preferably, the supporting substrate 12 has a thickness of 10 μm to 150 μm. A thermal conductivity of the insulating film 14 is lower than that of the silicon active layer 16 but higher than that of SiO₂, at a normal temperature.

This application is based on Japanese patent application NO. 2005-192327, the content of which is incorporated hereinto by reference.

### BACKGROUND

1. Technical Field

The present invention relates to a semiconductor device and a method of manufacturing the same.

2. Related Art

Recently, SOI (Silicon On Insulator) substrates have come to be focused on, for use as a semiconductor substrate for a semiconductor device. The SOI substrate is constituted of a supporting substrate, an insulating film provided on the supporting substrate, and a silicon layer provided on the insulating film. Such SOI substrate enables electrically isolating semiconductor elements such as transistors formed on the silicon layer, from one another completely. Accordingly, the SOI substrate is more advantageous in increasing the integration level and operation speed, as well as in reducing the power consumption, than a bulk silicon substrate.

The insulating film of the SOI substrate is generally constituted of a SiO₂ film. The thermal conductivity of SiO₂ is, however, as low as only one hundredth of that of silicon. Accordingly, heat generated in the silicon layer is restricted from being released outward, in a semiconductor device that includes the SOI substrate. This has led to development of a SOI substrate that can efficiently release the heat.

For example, Japanese Laid-open patent publication No. H09-27604 (Patent Document 1) discloses a SOI substrate that includes an insulating film having a higher thermal conductivity than the SiO₂ film, such as a silicon carbide film. Accordingly, it is known that employing a material having a high thermal conductivity as the insulating film of the SOI substrate leads to improvement in heat release performance.

Prior arts related to the present invention include the following:
Japanese Laid-open patent publication No. H09-27604,
Japanese patent publication No. 3350405,
Japanese Laid-open patent publication No. H10-95189,
Japanese Laid-open patent publication No. 2004-349428,
Japanese patent publication No. 3129020,
Japanese Laid-open patent publication No. 2004-158545,
Japanese Laid-open patent publication No. 2002-110871, and
Japanese patent publication No. 3022178.

### SUMMARY OF THE INVENTION

In the case of the SOI substrate according to the Patent Document 1, however, the supporting substrate suppresses the heat release because of having a certain thickness, even though the insulating film has a high thermal conductivity. Accordingly, such technique still has a room for improvement, in the aspect of heat release efficiency.

Especially when the SOI substrate is utilized as a substrate for a power MOSFET, high heat release efficiency is required for releasing the heat generated at the FET. FIG. 7 represents an example of such FET. A load drive circuit shown in FIG. 7 includes a FET 101 that drives a load 103, and a clamp circuit 102 connected between a gate and a drain of the FET 101. The clamp circuit 102 serves to restrict the voltage between the gate and the drain from exceeding a predetermined clamp voltage.

The output voltage and the output current of the load driver circuit shown in FIG. 7 fluctuate generally as shown in FIG. 8. Here, the output voltage means the voltage on the drain side of the FET 101 (the side to which the load 103 is connected), and the output current means the current running therethrough. In FIG. 8, lines L1, L2 respectively represent the fluctuation of the output voltage and the output current. Times t₀, t₁ represent the time when the FET 101 is turned off and the time when the output current becomes zero, respectively. Accordingly, (t₁-t₀) corresponds to the current-off time.

As shown in FIG. 8, at the moment that the FET 101 is turned off, the output voltage sharply rises because the load 103 attempts to keep supplying a current. When the output voltage exceeds the clamp voltage, a current runs from the drain to the gate of the FET 101 through the clamp circuit 102, by which the FET 101 is turned on. By such action, the energy stored in the load 103 is consumed at the FET 101, so that at the time t₁ the output current becomes zero, and the output voltage becomes equal to a power source voltage.

Thus in the load driver circuit shown in FIG. 7, a short pulse is generated from the output voltage. The term of short pulse will be herein defined as a pulse having a pulse width of 10⁻⁵ to 10⁻⁴ second, both inclusive.

According to the present invention, there is provided a semiconductor device comprising a SOI substrate including a supporting substrate, a substrate insulating film provided on the supporting substrate, and a silicon layer provided on the substrate insulating film; wherein a thermal conductivity of the substrate insulating film is lower than that of the silicon layer but higher than that of a silicon oxide film, at a normal temperature; and 10 μm≦d≦150 μm is satisfied, where d represents a thickness of the supporting substrate.

In the semiconductor device thus constructed, the insulating film having a higher thermal conductivity than a silicon oxide film is employed as the substrate insulating film. Also, the supporting substrate is formed in a thickness of 10 μm to 150 μm, both inclusive. As will be proven by a subsequently described simulation, heat release efficiency under a short pulse is improved, when the supporting substrate is formed within such thickness range. In addition, the thinner the supporting substrate is, the better heat release efficiency can be achieved under a long pulse (pulse having a pulse width longer than 10⁻⁴ second). Accordingly, the proposed semiconductor device allows achieving high heat release efficiency in both regions of the short pulse and the long pulse. Consequently, heat generated in the silicon layer can be efficiently released outside of the SOI substrate, through the substrate insulating film and the supporting substrate.

According to the present invention, there is also provided a method of manufacturing a semiconductor device, comprising preparing a SOI substrate including a supporting substrate, a substrate insulating film provided on the supporting substrate, and a silicon layer provided on the substrate insulating film; and making the supporting substrate in the SOI substrate thinner; wherein a thermal conductivity of the substrate insulating film is lower than that of the silicon layer but higher than that of a silicon oxide film, at a normal temperature.

The method of manufacturing thus arranged provides a semiconductor device that includes the SOI substrate including the insulating film having a higher thermal conductivity than a silicon oxide film. Further, in such semiconductor device, the SOI substrate includes the thinly shaped supporting substrate. Consequently, the proposed method provides the semiconductor that allows heat generated in the silicon layer to be efficiently released outside of the SOI substrate, through the substrate insulating film and the supporting substrate.

The present invention provides a semiconductor device that offers excellent heat release efficiency, and a method of manufacturing such semiconductor device.

### BRIEF DESCRIPTION OF THE DRAWINGS

The above and other objects, advantages and features of the present invention will be more apparent from the following description taken in conjunction with the accompanying drawings, in which:

FIG. 1 is a schematic cross-sectional view showing a semiconductor device according to the first embodiment of the present invention;

FIG. 2 is an enlarged schematic cross-sectional view showing an isolation region in the semiconductor device of FIG. 1;

FIGS. 3A to 3C are schematic cross-sectional views progressively showing a method of manufacturing the semiconductor device of FIG. 1;

FIGS. 4A to 4C are schematic cross-sectional views progressively showing a method of manufacturing the semiconductor device of FIG. 1;

FIG. 5 is a schematic cross-sectional view showing a semiconductor device according to the second embodiment of the present invention;

FIGS. 6A to 6C are schematic cross-sectional views progressively showing a method of manufacturing the semiconductor device of FIG. 5;

FIG. 7 is a circuit diagram of a load drive circuit;

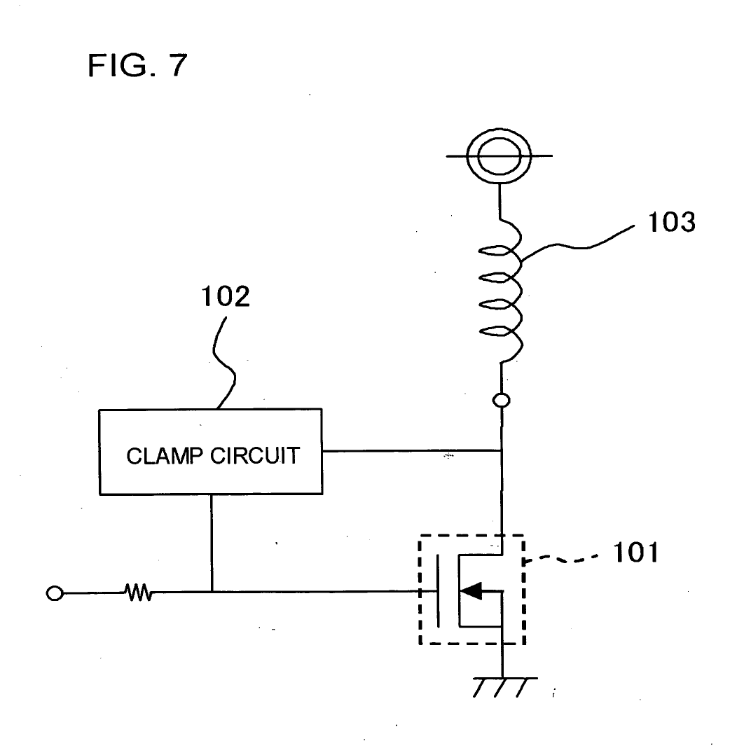

FIG. 8 is a graph schematically showing a fluctuation of an output voltage and an output current in the load drive circuit of FIG. 7; and

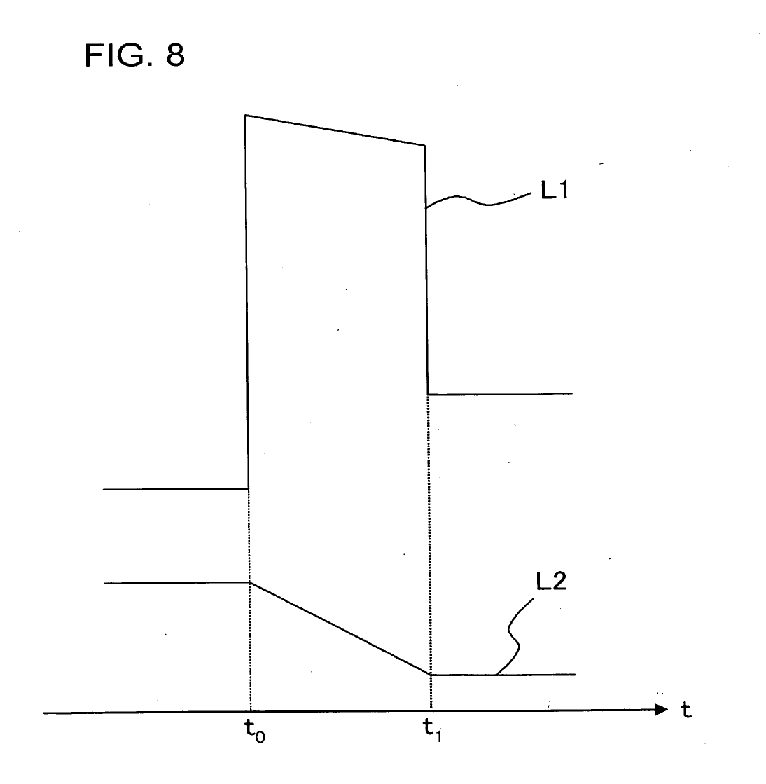

FIGS. 9A and 9B are graphs showing results of thermal simulations based on a finite element method.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereunder, exemplary embodiments of a semiconductor device and a method of manufacturing the same according to the present invention will be described in details, referring to the accompanying drawings. In the drawings, same constituents are given the identical numerals, and duplicating description may be omitted where appropriate.

### FIRST EMBODIMENT

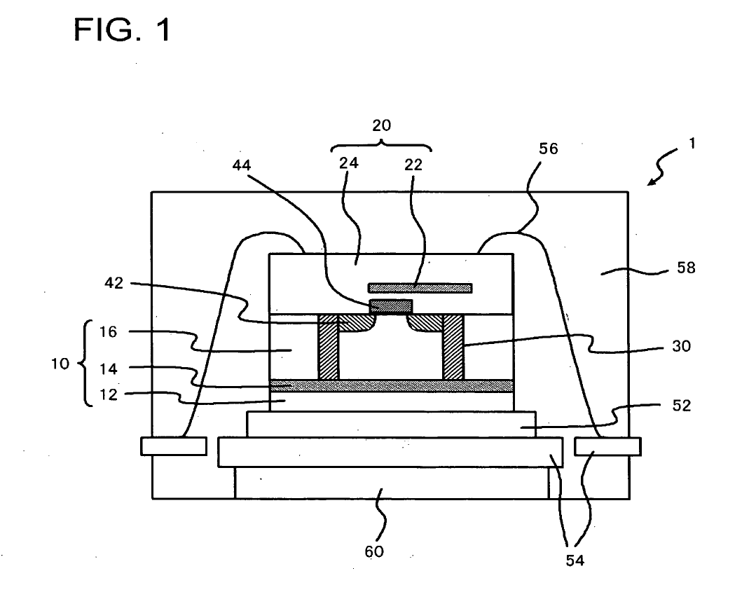

FIG. 1 is a schematic cross-sectional view showing a semiconductor device according to the first embodiment of the present invention. The semiconductor device 1 includes a SOI substrate 10, an interconnect layer 20, and an isolation region 30. The SOI substrate 10 includes a supporting substrate 12, an insulating film 14 (substrate insulating film) provided on the supporting substrate 12, and a silicon active layer 16 (silicon layer) provided on the insulating film 14.

When the thickness of the supporting substrate 12 is denoted by d, it is preferable that 10 μm≦d≦150 μm is satisfied. Above all, it is desirable that d is 50 μm. In this embodiment, the supporting substrate 12 is a silicon substrate.

The insulating film 14 is a highly heat-conductive layer. The thermal conductivity of the insulating film 14 is lower than that of the silicon active layer 16, but higher than that of SiO₂, at a normal temperature. The silicon active layer 16 may have the thickness of 2 to 10 μm, generally approx. 5 μm.

On the silicon active layer 16 of the SOI substrate 10, the interconnect layer 20 is provided. The interconnect layer 20 includes an interconnect 22 and an insulating interlayer 24. The insulating interlayer 24 is a highly heat-conductive layer. The thermal conductivity of the insulating interlayer 24 is lower than that of the silicon active layer 16, but higher than that of SiO₂, at a normal temperature. The interconnect layer 20 has the thickness of 1 to 3 μm, when constituted of a single interconnect layer. Preferably, the supporting substrate 12 may be thinner than the total thickness of the silicon active layer 16 and the interconnect layer 20, and more preferably thinner than the silicon active layer 16.

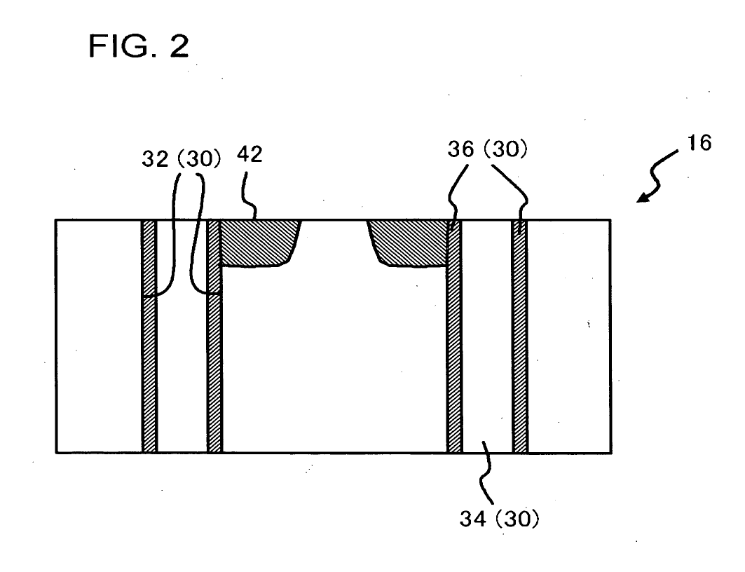

The silicon active layer 16 of the SOI substrate 10 includes the isolation region 30. As shown in FIG. 2, the isolation region 30 includes a trench 32, a conductive layer 34 and a buried insulating film 36. FIG. 2 extracts the silicon active layer 16, out of the semiconductor device 1. The trench 32 is provided so as to penetrate the silicon active layer 16. The trench 32 contains therein the conductive layer 34 and the buried insulating film 36. To be more detailed, the conductive layer 34 is provided with a predetermined space from the sidewall of the trench 32, and the buried insulating film 36 is provided so as to fill in the gap between the trench 32 and the conductive layer 34. The buried insulating film 36 has a function of isolation. Also, buried insulating film 36 is a highly heat-conductive layer. The thermal conductivity of the buried insulating film 36 is lower than that of the silicon active layer 16, but higher than that of SiO₂, at a normal temperature.

Materials employable as the insulating film 14, the insulating interlayer 24 and the buried insulating film 36 include Si₃N₄ (silicon nitride), BN (boron nitride), AlN (aluminum nitride), Al₂O₃ (alumina), a CVD diamond, and a DLC (diamond-like carbon). When employing the BN, it is especially desirable from the viewpoint of thermal conduction to employ a c-BN (cubic boron nitride). The materials of the insulating film 14, the insulating interlayer 24 and the buried insulating film 36 may be the same, or different from one another.

The foregoing materials have a thermal conductivity in the following range in general. It is to be noted that the following values may fluctuate depending on methods of manufacturing and conditions such as temperature.
Si₃N₄: 33.5 W/(m·K)
BN: 57 W/(m·K)
c-BN: 200 to 900 W/(m·K)
AlN: 320 W/(m·K)
Al₂O₃: 30 W/(m·K)
CVD diamond: 600 to 1000 W/(m·K)
DLC: 20 W/(m·K)

Referring back to FIG. 1, the silicon active layer 16 and the interconnect layer 20 include a source/drain region 42 and a gate electrode 44, respectively. The source/drain region 42 and the gate electrode 44 are electrically connected to the interconnect 22 via a contact plug, which is not shown in the drawings. The source/drain region 42 and the gate electrode 44 constitute a FET (field effect transistor) in the semiconductor device 1.

The SOI substrate 10 and the interconnect layer 20 thus configured are mounted on a lead frame 54 via a mounting material 52. On the other side of the lead frame 54 opposite to the mounting material 52, a heat spreader 60 is provided as a heat release member. The interconnect layer 20 and the lead frame 54 are mutually connected via a bonding wire 56. In addition, the SOI substrate 10 and the interconnect layer 20 are covered with a seal resin 58.

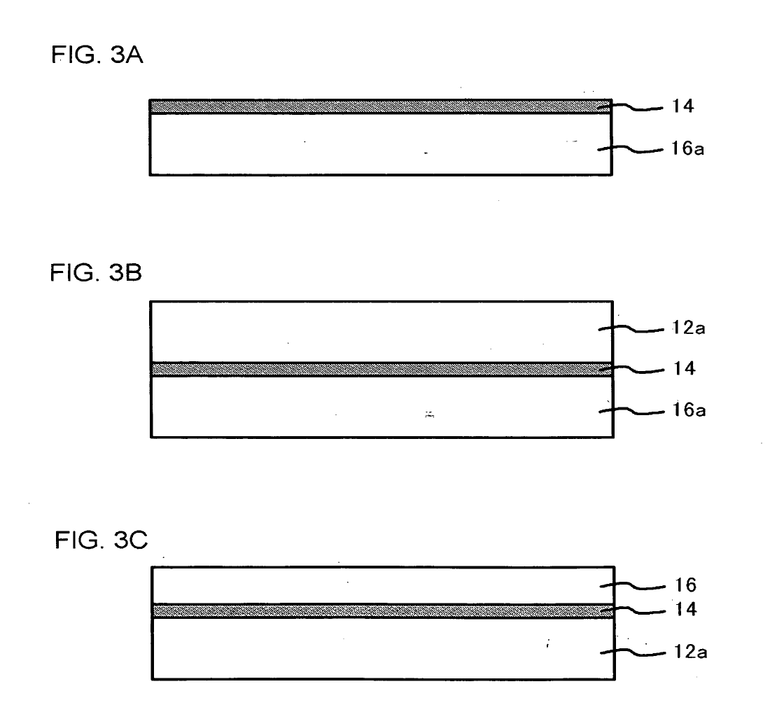

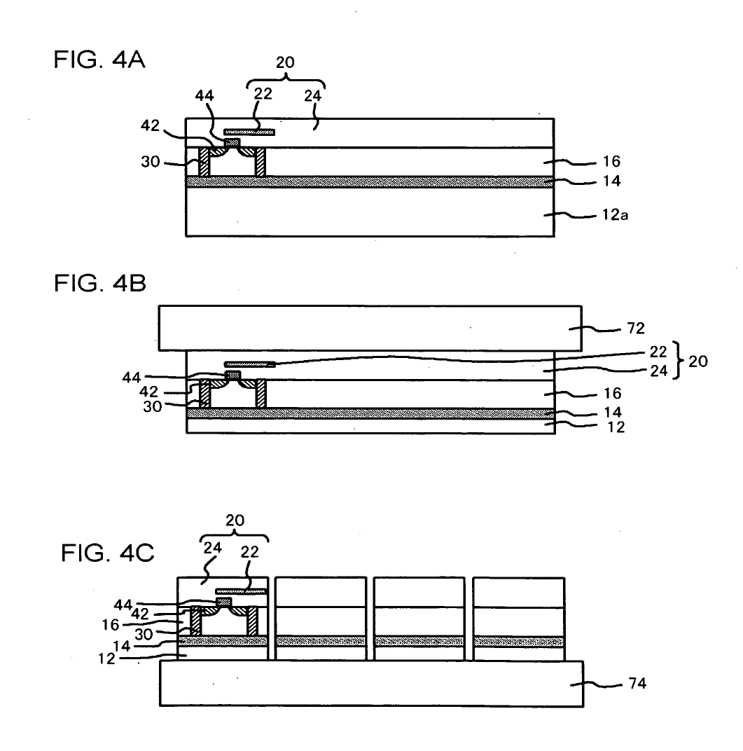

Referring now to FIGS. 3A to 3C and 4A to 4C, a method of manufacturing the semiconductor device 1 will be described, as the first embodiment of the method of manufacturing a semiconductor device according to the present invention. Firstly the insulating film 14 is deposited on a silicon substrate 16a, which is to subsequently become the silicon active layer 16 (FIG. 3A). For example, as to ceramic, thermal conduction takes place primarily based on lattice vibration (phonon), and if the thermal vibration of the lattice is a completely harmonic vibration, there is no resistance against the thermal vibration. However if a complicated crystalline structure or an impurity is present, the motion of thermal conduction medium becomes inharmonious, by which the thermal conduction is lowered. An insulating material that has a strong covalent bond and a large interatomic bond, and is light in weight has a high thermal conductivity. When employing, for example, a Si₃N₄ film as the insulating film 14, it is preferable to perform P-CVD (plasma chemical vapor deposition) or the like to form the insulating film in the thickness of approx. 0.3 to 1 μm, which is sufficient for achieving required electrical insulation.

If necessary, a sintering process may be carried out in order to obtain a better form of crystallization of the insulating film 14. When employing a BN film as the insulating film 14, PLD (pulse laser deposition) may be performed to form the insulating film in the thickness of a few to approx. 10 μm. For facilitating a depletion layer of an active layer to expand thus to increase the breakdown voltage of the connection, it is more advantageous to form a thick insulating film having a high dielectric constant. It is also effective to interpose an adhesion layer such as Ti, or an adhesive, for improving the adhesion. Further, a plurality of films may be stacked, to thereby alleviate a stress.

Referring to FIG. 3B, a supporting substrate 12a, which is to subsequently become the supporting substrate 12, is adhered to the surface of the insulating film 14 opposite to the silicon substrate 16a. A plasma process may be performed to activate the surface of the insulating film 14, so as to execute a cold bonding. Alternatively, an inorganic adhesive may be employed for adhesion. Then the silicon substrate 16a is polished until a predetermined thickness is obtained, thus to form the silicon active layer 16 (FIG. 3C). At this stage, the SOI substrate is obtained.

Upon forming the FET including the source/drain region 42 and the gate electrode 44, the trench 32 (Ref. FIG. 2) is formed so as to penetrate the silicon active layer 16. For further assuring the electrical insulation by the buried insulating film 36 in the trench 32, it is also effective to form the trench in a tapered or rounded shape, thus to alleviate field concentration. Then the conductive layer 34 and the buried insulating film 36 are formed so as to fill in the trench 32. For forming the conductive layer 34 and the buried insulating film 36, it is preferable to first form the buried insulating film 36 so as to cover the sidewall of the trench 32, then to fill the remaining space (i.e. space not occupied by the buried insulating film 36) in the trench 32 with the conductive layer 34. At this stage, the isolation region 30 is obtained. This is followed by formation of the interconnect layer 20 on the silicon active layer 16 (FIG. 4A). Here, the insulating interlayer 24 of the interconnect layer 20 and the buried insulating film 36 may be formed at a time. Likewise, the interconnect 22 and the conductive layer 34 may be formed at a time.

It is to be noted that, although the interconnect 22, the isolation region 30 and the FET are actually fabricated in a plurality of numbers respectively, FIGS. 3A through 4C only show a portion of those, for the sake of explicitness.

Then a supporting member 72 is adhered to the interconnect layer 20. This process may be performed with an adhesive or an adhesive sheet. Examples of the material of the supporting member 72 include a ceramic and a plastic. After that, the supporting substrate 12a is made thinner. Specifically, the supporting substrate 12a is polished to a predetermined thickness, with the supporting member 72 remaining adhered to the interconnect layer 20, thus to form the supporting substrate 12. In this process, it is preferable to reduce the thickness of the supporting substrate 12a so that the thickness d of the supporting substrate 12 fall in the range of 10 to 150 μm (FIG. 4B).

A supporting member 74 is then adhered to the supporting substrate 12, after which the supporting member 72 is removed. Then a dicing process is performed, with the supporting member 74 adhered, thus to split the SOI substrate 10 and the interconnect layer 20 into individual pieces (FIG. 4C). After that, the chips thus split are mounted on the lead frame 54. Upon executing a wire bonding process with a bonding wire 56, a seal resin 58 is provided to enclose the chip. Throughout the foregoing steps, the semiconductor device 1 shown in FIG. 1 is obtained.

This embodiment offers the following advantageous effects. This embodiment employs an insulating film having a higher thermal conductivity than SiO₂ as the insulating film 14 in the SOI substrate 10. Also, since the supporting substrate 12 is made thinner, heat generated at the silicon active layer 16 can be efficiently released outside the SOI substrate 10, through the insulating film 14 and the supporting substrate 12. This embodiment accordingly provides the semiconductor device 1 that offers excellent heat release efficiency, as well as a method of manufacturing such semiconductor device.

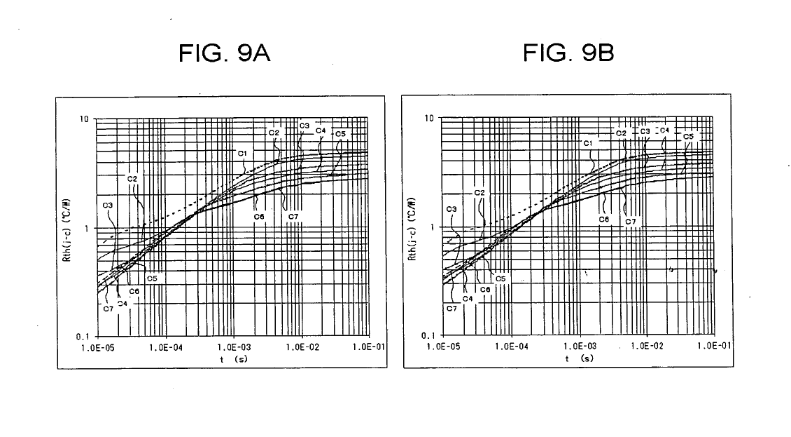

FIGS. 9A and 9B are graphs showing results of thermal simulations based on the finite element method. In these graphs, the horizontal axis represents a pulse width (second), and the vertical axis a thermal impedance (° C./W). Curved lines C1 to C7 respectively correspond to the conditions specified below. Specifically, the curved line C1 represents the case where silicon oxide is employed as the insulating film 14, while the curved lines C2 to C7 the cases where silicon nitride is employed.
C1: supporting substrate 280 μm, silicon oxide 0.5 μm
C2: supporting substrate 280 μm, silicon nitride 0.5 μm
C3: supporting substrate 150 μm, silicon nitride 0.5 μm
C4: supporting substrate 100 μm, silicon nitride 0.5 μm
C5: supporting substrate 50 μm, silicon nitride 0.5 μm
C6: supporting substrate 10 μm, silicon nitride 0.5 μm
C7: supporting substrate 5 μm, silicon nitride 0.5 μm

The silicon nitride employed for FIG. 9A proved to have the thermal conductivity of 29 W/mK, while the silicon nitride employed for FIG. 9B the thermal conductivity of 7.3 W/mK. As is apparent from these graphs, heat release efficiency under a short pulse becomes high when the supporting substrate 12 has the thickness of 10 μm to 150 μm. Above all, heat release is especially high when the supporting substrate 12 is 50 μm thick. In contrast, heat release efficiency under a long pulse becomes higher as the supporting substrate becomes thinner. Also, upon comparison of the curved lines C1 and C2, it is understood that, when the supporting substrates have the same thickness, employing an insulating film having a higher thermal conductivity than the silicon oxide film as the insulating film 14 results in improved heat release efficiency. It is now proven, therefore, that the semiconductor device 1 offers high heat release efficiency in both regions of the short pulse and the long pulse.

Also when the supporting substrate 12 is thinner than the total thickness of the silicon active layer 16 and the interconnect layer 20, significantly high heat release efficiency can be achieved. In particular, forming the supporting substrate 12 to be thinner than the silicon active layer 16 allows achieving still better heat release efficiency.

The insulating interlayer 24 in the interconnect layer 20 has a higher thermal conductivity than SiO₂. Accordingly, the semiconductor device 1 can efficiently release the heat generated at the silicon active layer 16 not only through the insulating film 14 and the supporting substrate 12, but also through the interconnect layer 20. However, it is not imperative to employ an insulating film having a higher thermal conductivity than SiO₂ as the insulating interlayer 24.

In the semiconductor device 1, the semiconductor elements such as the FET are electrically isolated from one another completely, because the isolation region 30 is provided so as to penetrate the silicon active layer 16. Also, the buried insulating film 36 buried in the isolation region 30 has a higher thermal conductivity than SiO₂. Accordingly, the heat generated at the silicon active layer 16 can be efficiently released also through the isolation region 30. Further in this embodiment, the isolation region 30 includes the conductive layer 34. This serves to further enhance the heat release effect through the isolation region 30. It is not, however, imperative to form the conductive layer 34 in the isolation region 30, and the buried insulating film 36 alone may be provided. It is not imperative either, to employ an insulating film having a higher thermal conductivity than SiO₂ as the buried insulating film 36.

Meanwhile, the Japanese patent publication No. 3350405 and Japanese Laid-open patent publication No. H10-95189 disclose a semiconductor device including a SOI substrate from which a supporting substrate is removed by etching. Removing thus the supporting substrate can increase the heat release effect of the SOI substrate. For completely removing the supporting substrate, however, the etching process is performed until the insulating film in the SOI substrate is exposed, by which the surface of the insulating film may become rough. This naturally leads to degradation in film quality of the insulating film and interface deterioration. Instead, leaving a thin supporting substrate as the foregoing embodiment can prevent the degradation in film quality of the insulating film, while still improving the heat release effect of the SOI substrate.

### SECOND EMBODIMENT

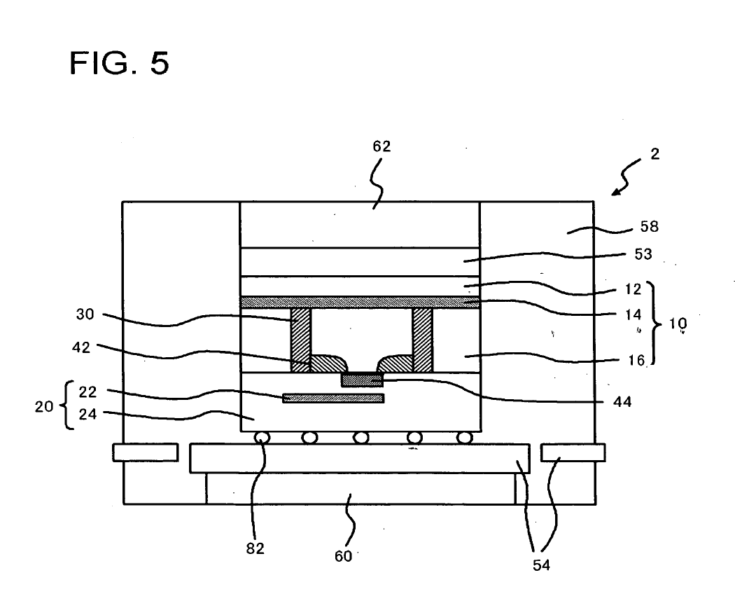

FIG. 5 is a schematic cross-sectional view showing a semiconductor device according to the second embodiment of the present invention. The semiconductor device 2 includes the SOI substrate 10, the interconnect layer 20, and the isolation region 30. The SOI substrate 10, the interconnect layer 20, and the isolation region 30 are similarly configured to those shown in FIG. 1.

In the semiconductor device 2, the SOI substrate 10 and the interconnect layer 20 are bonded on the lead frame 54 by flip-chip bonding. Accordingly the interconnect layer 20 and the lead frame 54 are connected via bumps 82. Also, a heat spreader 62 serving as a heat release member is provided on the supporting substrate 12, via a mounting material 53.

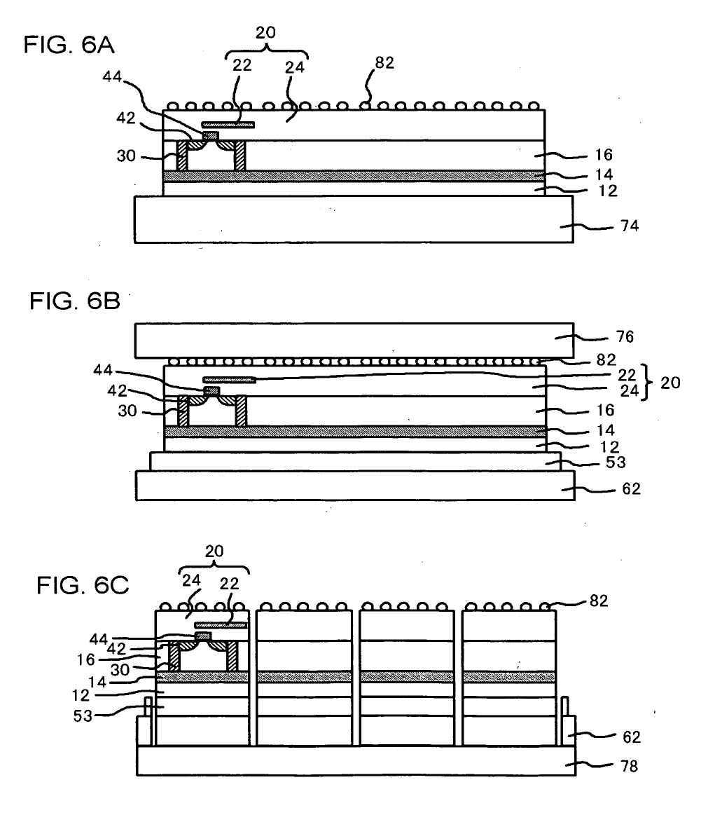

Referring to FIGS. 6A to 6C, a method of manufacturing the semiconductor device 2 will be described, as the second embodiment of the method of manufacturing a semiconductor device according to the present invention. Firstly the SOI substrate is prepared similarly to the steps of FIGS. 3A to 3C. Then the isolation region 30, the source/drain region 42, the gate electrode 44 and the interconnect layer 20 are sequentially formed, as described referring to FIG. 4A. After that, as stated referring to FIG. 4B, the supporting substrate 12 is made thinner with the supporting member 72 adhered to the interconnect layer 20.

After adhering the supporting member 74 to the supporting substrate 12, the supporting member 72 is removed. Under such status, the bumps 82 are formed on the interconnect layer 20 (FIG. 6A). Here, a highly heat-conductive film, having a higher thermal conductivity than SiO₂, such as the insulating interlayer 24 may be provided among the bumps 82. Then a supporting member 76 is adhered to the bumps 82, after which the supporting member 74 is removed. Under such status, the supporting substrate 12 and the heat spreader 62 are bonded via the mounting material 53 (FIG. 6B). After adhering a supporting member 78 to the heat spreader 62, the supporting member 76 is removed. A dicing process is performed at this stage, thus to split the SOI substrate 10, the interconnect layer 20, the mounting material 53 and the heat spreader 62 into individual pieces (FIG. 6C).

The chips thus split are mounted on the lead frame 54 with the face oriented downward by flip-chip bonding, and the seal resin 58 is provided for enclosing the chip. Since the seal resin 58 has a poor thermal conductivity, it is desirable to execute the flip-chip bonding over a region as large as possible, for facilitating heat release. Throughout the foregoing steps, the semiconductor device 2 shown in FIG. 5 can be obtained.

This embodiment also employs an insulating film having a higher thermal conductivity than SiO₂ as the insulating film 14 in the SOI substrate 10. Also, since the supporting substrate 12 is made thinner, heat generated at the silicon active layer 16 can be efficiently released outside the SOI substrate 10, through the insulating film 14 and the supporting substrate 12. This embodiment accordingly provides the semiconductor device 2 that offers excellent heat release efficiency, as well as a method of manufacturing such semiconductor device. Further, as in the semiconductor device 1, the insulating interlayer 24 in the interconnect layer 20 has a higher thermal conductivity than SiO₂. Accordingly, the semiconductor device 2 can also efficiently release the heat generated at the silicon active layer 16 not only through the insulating film 14 and the supporting substrate 12, but also through the interconnect layer 20.

Still further, the heat spreaders 60 and 62 are provided on the respective sides of the SOI substrate 10. Such structure makes the semiconductor device 2 even more capable of releasing the heat generated at the silicon active layer 16, both through the insulating film 14 and the supporting substrate 12, and through the interconnect layer 20.

It is apparent that the present invention is not limited to the above embodiment, and may be modified and changed without departing from the scope and spirit of the invention.

What is claimed is:

1. A semiconductor device comprising:
a SOI substrate including a supporting substrate, a substrate insulating film provided on said supporting substrate, and a silicon layer provided on said substrate insulating film;
wherein a thermal conductivity of said substrate insulating film is lower than that of said silicon layer but higher than that of a silicon oxide film, at a normal temperature; and
10 μm≦d≦150 μm is satisfied, where d represents a thickness of said supporting substrate.

2. The semiconductor device according to claim 1, further comprising an interconnect layer provided on said silicon layer in said SOI substrate;
wherein said supporting substrate is thinner than a total thickness of said silicon layer and said interconnect layer.

3. The semiconductor device according to claim 2,
wherein said supporting substrate is thinner than said silicon layer.

4. The semiconductor device according to claim 1, further comprising an interconnect layer provided on said silicon layer in said SOI substrate;
wherein a thermal conductivity of an insulating interlayer in said interconnect layer is lower than that of said silicon layer but higher than that of said silicon oxide film, at a normal temperature.

5. The semiconductor device according to claim 1, further comprising:
a trench provided so as to penetrate said silicon layer;
a buried insulating film buried in said trench and having a function of isolation;
wherein a thermal conductivity of said buried insulating film is lower than that of said silicon layer but higher than that of said silicon oxide film, at a normal temperature.

6. The semiconductor device according to claim 5, further comprising a conductive film provided in said trench with a predetermined space from a sidewall of said trench;
wherein said buried insulating film is provided so as to fill in a gap between said sidewall of said trench and said conductive film.

7. A method of manufacturing a semiconductor device, comprising:
preparing a SOI substrate including a supporting substrate, a substrate insulating film provided on said supporting substrate, and a silicon layer provided on said substrate insulating film; and
making said supporting substrate in said SOI substrate thinner;
wherein a thermal conductivity of said substrate insulating film is lower than that of said silicon layer but higher than that of a silicon oxide film, at a normal temperature.

8. The method according to claim 7,
wherein 10 μm≦d≦150 μm is satisfied, where d represents a thickness of said supporting substrate having been made thinner.

9. The method according to claim 7, further comprising:
forming an interconnect layer including an insulating interlayer having a thermal conductivity lower than that of said silicon layer but higher than that of said silicon oxide film at a normal temperature, on said silicon layer in said SOI substrate.

10. The method according to claim 7, further comprising:
forming a trench so that said trench penetrate said silicon layer in said SOI substrate; and
forming a buried insulating film having a function of isolation so that said buried insulating film fill in said trench;
wherein a thermal conductivity of said buried insulating film is lower than that of said silicon layer but higher than that of said silicon oxide film, at a normal temperature.
